(19) United States
(12) Patent Application Publication
(10) Pub. No.: US 2026/0124823 A1
(43) Pub. Date: May 7, 2026

(54) FOLDED FLEXIBLE CIRCUIT FOR AUTOMOTIVE LAMINATE

(71) Applicant: AGP WORLDWIDE OPERATIONS GMBH, Zug (CH)

(72) Inventors: Araz DARBA, Ghent (BE); Andrés Fernando SARMIENTO SANTOS, Canton, MI (US); Rafael AGUILERA, Ghent (BE)

(21) Appl. No.: 19/116,218

(22) PCT Filed: Oct. 2, 2023
(86) PCT No.: PCT/IB2023/059875

§ 371 Date: Mar. 27, 2025

Related U.S. Application Data
(60) Provisional application No. 63/377,894, filed on Sep. 30, 2022.

(51) Int. Cl. B32B 17/10; H05K 1/02

(52) U.S. Cl. CPC B32B 17/10036; B32B 17/10293; B32B 17/10376; H05K 1/028; B32B 2305/34; B32B 2307/202; B32B 2307/206; B32B 2307/7376; B32B 2605/00; H05K 2201/055

(57) ABSTRACT

The complexity of modern automotive glazing is increasing as more and more technology is being integrated with the glazing. As the industry moves towards full autonomous electric vehicles and as consumers demand increased levels of comfort, convenience, and safety this trend will only increase. It is now common to have electrical components embedded within laminated glazing. However, making electrical connections to embedded components can be challenging. The flexible circuit of the disclosure, which can provide an electrical connection to multiple complex circuits, comprises a flexible circuit with at least one insulating layer, at least one conductive layer and with at least one sharp fold in the flexible circuit. This approach substantially reduces the quantity of material that is wasted, facilitates assembly of the laminate, and reduces cost.

### FIELD OF THE DISCLOSURE

The disclosure is related to the field of laminated automotive glazing.

### BACKGROUND OF THE DISCLOSURE

The complexity of modern automotive glazing has been increasing at a rapid rate as the result of a number of trends in the automotive industry.

In response to the regulatory requirements for increased automotive fuel efficiency as well as the growing public awareness and demand for environmentally friendly products, automotive original equipment manufacturers, around the world, have been working to improve the efficiency of their vehicles.

One of the widely employed methods to improve efficiency has been to reduce vehicle weight. This is sometimes accomplished by increasing the glazed area of the vehicle, displacing heavier materials with glass and plastic. This is often done in conjunction with a reduction in the overall size of the vehicle. Unfortunately, the reduction in cabin volume can lead to an undesirable, cramped, and claustrophobic feel. However, it has been found that increasing the glazed area, in addition to reducing weight, helps to offset this effect by giving the occupants a wider field of view and admitting more natural light.

Roof glazing is highly effective in this respect. Roof glazing, once limited to an area immediately above the front seat, have been getting larger and larger. We now see roof glazing that comprise a substantial portion of the vehicle roof. These large glazing are known as panoramic roofs.

A panoramic roof is comprised substantially of glass. The roof glazing may be comprised of a single or multiple glazing. One or more of the glazing may be fixed or movable. The glazing may be laminated, tempered or a mixture of both types.

The large panoramic glass roof gives the vehicle an airy and luxurious look. On new cars, the panoramic roof has become a popular option that has seen rapid growth over the last several years. In recent years, on models offered with a panoramic roof offered as an option the take rate has been high. This trend is predicted to accelerate in the coming years.

Interestingly, while the predecessor to the panoramic roof, the “sunroof”, let in light and could be opened to let in air, panoramic roofs sometimes have panels that are fixed in place and do not open. Models equipped with panoramic roofs that open require complex and expensive mechanisms that tend to be prone to warranty issues. In addition, panoramic roofs sometimes do not let very much light into the vehicle. Due to the large surface area exposed to the sun, the panoramic roof is often designed to transmit as little as 3% visible light to reduce the need for a shade, another added cost and potential warranty item. The panoramic roof may be one option that is purchased more for appearance and aesthetics rather than function.

Another important trend is the move toward full autonomous operation. Today, most new vehicles come with some level of automated driver assistance system, ADAS, as standard equipment. Automated driver assistance systems are just one of the innovative technologies that the vehicle glazing has become an integral and essential part of. Many of the automotive manufacturers are now making driver assistance systems, which were an expensive option not too many years ago, standard equipment on many if not all of their models.

With the vehicle glazing occupying a large percent of the vehicle exterior and interior surface area, it is increasingly being integrated with the various sensors and other components needed to enable the driver assist systems.

Another trend is the transition from internal combustion engine (ICE) powered vehicles to full electric. Most large automobile manufacturers have announced plans to transition from primarily ICE powered vehicles to battery powered full electric. We have also seen several new automobile manufacturers emerge producing battery electric vehicles exclusively.

One of the challenges of full electric battery powered vehicles is range. The reduction in range due to the heating and cooling load of the vehicle is especially a problem due to the substantial amount of energy required.

The typical internal combustion engine (ICE) powered vehicle is not extremely efficient at turning the energy from the fuel into kinetic energy. More of the energy is converted into heat than motion. Managing this waste heat has long been one of the major challenges faced in the design of this type of vehicle. However, one of the benefits of this inefficiency is that it provides a ready and essentially free source of power for heating the cabin and clearing the glazing of ice and fog. The typical ICE vehicle is equipped with a hot air system having a capacity of 4,000 watts or greater. This compares to the 1,000-1,500-watt capacity of the typical automotive electrical alternator.

However, as the efficiency of ICE vehicles has increased, some high efficiency, small displacement engine vehicles, especially those sold in parts of the world with a cold climate, have had to add resistive heating elements to provide sufficient cabin heat. One advantage of resistive heating is that the heat is provided on demand. There is no lag waiting for the engine heat up. A typical approach has been to add positive temperature coefficient resistive heating elements, which are self-regulating and inexpensive, to the hot air system to supplement to the air/liquid heat exchanger.

The move towards hybrid-electric and all-electric vehicles has further increased the need for resistive heating. With an all-electric battery powered drive train, only limited waste heat is available from the battery pack. While many hybrids may be equipped with an ICE to supplement and charge the battery the engine tends to be small, very efficient and is often not operated continuously while the vehicle is in use. This is also a problem even in non-electric ICE vehicles which utilize engine start/stop technology where the engine shuts off when the vehicle is not in motion. During a long stop in traffic, there may not be enough heat available to maintain the cabin temperature and to keep the glazing clear.

The primary problem with resistive heating is the large amount of energy that it can consume. This is especially important for all-electric vehicles where cold weather can significantly reduce range due to the demands of the cabin heating and deice/defog system. As an example, an electric vehicle with a battery capacity of 40 KW hours, operating a 4,000-watt hot air system for just one hour would use 10% of its capacity and have its range reduced by 10% contributing to what is known as “range anxiety”.

As the industry also simultaneously moves towards semi and full autonomous operation, rapid clearing of the windshield, where essential components of the autonomous hardware are mounted, has become even more important. This is essential for a short drive away time.

Today, many windshield are equipped with multiple resistive heating circuits. One for the wiper rest area, to melt any packed snow swept by the wiper and to keep the wiper blades from freezing to the windshield, a defroster for the driver assistance cameras, and a third for clearing the vision zones of the windshield for the driver. While an embedded defroster circuit is much more efficient than a hot air system, it still requires a lot of energy and is a significant load on the traction or secondary battery system. It would be desirable to divide the heated circuits even further so the energy can be applied only where it is needed. As an example, the windshield defroster circuit may be configured with a high-power zone that clears in five minutes for the ADAS cameras and primary vision zones, a secondary zone that clears in 10 minutes and a tertiary zone that clears in 20 minutes.

All of these circuits require multiple connections to switch separately. If the circuit resistive element is comprised of a conductive coating or embedded wire within the laminate, the connection must be internal to the laminate.

Keeping the interior cool can also significantly reduce the range of the vehicle. Very effective solar control coatings are available that can substantially reduce the solar load on the vehicle. However, they also prevent the sun from warming the interior during cold weather.

VLT films are films on which the level of light transmission and solar energy transmitted can be varied. There are many technologies available that can be used to control the level of light transmission. They include but are not limited to electrochromic, photochromic, thermochromic and electric field sensitive. Films incorporating the various technologies have been designed which can be incorporated into laminated glass. Of particular interest are suspended particle device (SPD) films, polymer dispensed liquid crystal (PDLC), and liquid crystal (LC) films all of which can quickly change their level of light transmittance in response to an electrical field. SPD is a type of VLT in which the level of tint can be controlled and varied in response to an applied electrical field. SPD goes from dark in the unpowered state to clear in the powered state. In an SPD film, microscopic droplets of liquid containing needle like opaque particles, known as light vales, are suspended in a polymer matrix. In the off state the particles are in a random state of alignment and block the transmission of light. The degree of alignment and resulting tint can be varied in response to the applied voltage. The level of light transmittance in the on and off states can also be shifted through changes to the thickness and composition of the active material. In the off state, it is still possible to see clearly through SPD. The primary drawback of SPD is its strong blue tint. Haze, sensitivity to heat, long term degradations due to UV exposure, the high operating voltage, and the limited range of light transmission are also issues.

PDLC is a light scattering VLT technology which goes from light scattering with high haze in the off state to clear in the on state. In a PDLC film, microscopic droplets of liquid crystal are suspended in a polymer matrix. In the off state the liquid crystals are in a random state of alignment scattering the light and providing privacy. When an electric field is applied, the crystals align and allow light to pass.

The degree of scattering can be controlled by varying the amplitude of the applied voltage. The level of light transmittance in the on and off states can also be shifted by changing the thickness and composition of the active material. PDLC is primarily a privacy product though it can also be used for solar control as it reduces the solar energy transmitted. The primary drawback of PDLC is the whitish color that it takes on in the off state. Like SPD, haze, the operating voltage, degradation from long term UV exposure and the range of light transmission are also issues.

Upon the loss of power, SPD and PLDC both fail in the dark state. For safety reasons, SPD and PDLC cannot be used in applications where an abrupt loss of visibility would be dangerous as is the case when power is lost. Both also require a relatively high alternating current voltage in the 50-100-volt range. The higher voltage increases the risk of shock and requires additional circuit protection and insulation.

Liquid Crystal (LC) technology is similar to PDLC. The active material in LC is also liquid crystal. However, rather than encapsulating the liquid crystal in a polymer matrix, the two conductive coated layers are separated by spacers, the edge is sealed and then the gap is filled with liquid crystal.

Laminates that incorporate these variable light transmittance technologies are sometime referred to as “smart” glass or switchable.

A minimum of two electrical connections, a hot and neutral, are needed to control the light transmission of VLT films. The hot wire carries the electricity from the power supply to the load. The neutral wire completes the circuit and carries electricity back to the power supply. Separately operated and switched circuits can be formed in VLT films by means of LASER ablation of the conductive coating. This allows for a single VLT film to have multiple circuits in which the level of light transmission can be varied. The film can be configured to display graphics. In one example, the film is configured to mimic the look of a traditional blind with multiple slats. Each “slat” requires two electrical connections. As an example, a film with fourteen “slats”, and a common neutral would require fifteen electrical connections, one to the common neutral and fourteen hot, one hot for each slat.

There are many other active electrical components that are finding their way into automotive laminates including but not limited to LEDs, antennas, displays, touch sensors, sound transducers, RFID transducers, distance sensors, and others.

Providing an electrical connection to these various components, located, and embedded within the laminate, can be a challenge.

As a rule of thumb, an object can be laminated without the need to compensate for thickness if the thickness is not more than a third of the total thickness of the one or more interlayers. The interlayer is soft at room temperature. During the lamination process, the interlayer or interlayers are processed at an elevated temperature and will flow to accommodate the added object if the object is thin enough. The maximum thickness will depend upon other factors such as the other dimensions of the object, the thickness of the glass, the strength of the glass, the specific interlayer and the time, temperature, and pressure of the lamination cycle. If the object is too thick, the glass may break. Objectionable distortion can occur due to the residual stress and distortion of the glass itself. With all other factors remaining the same, thinner is always better with respect to the risk of breakage and distortion.

It is not so much the thickness of the object as the rate of change in the thickness that causes problems. If a film of uniform thickness extends to the edge of glass, then the only issue will be wrinkling of the film as the flat film is forced to conform to the curvature of the glass. In this case, the one third rule does not apply. However, it is typical to cut back the film from the edge of glass so as to protect the edge of the film from exposure to external elements and to minimize the amount of film needed. This step change in thickness is where problems can occur. If the change is too great, a spacer may be needed. One method used to prevent breakage has been to insert a spacer running from the edge of the film to the edge of glass. In this way, the abrupt step change in thickness at the edge of the film is avoided.

If the object is around one third the thickness of the interlayer, then lamination may be successful. Other process parameters must also be adjusted. It is advisable to heat and soften the interlayer before vacuum is applied and to ramp up pressure at a slower rate than would otherwise be used.

Considering a laminate with a single layer of 0.76 mm thick interlayer, an object of up to around 0.25 mm in thickness can be laminated. With two standard interlayer layers, the object can be up to 0.5 mm thick.

For most of the components discussed, where only a small number of electrical connections are needed, a connector comprising a thin narrow conductor layer sandwiched between two insulating layers is often used. These connectors typically only have one or two separate conductors in each.

It is known in the art to LASER ablate circuits in a conductive coating applied to the glass to form circuits. However, these circuits, comprised of the conductive coating typically use the same type of thin conductor/insulating layer connector.

When multiple LED die are embedded, the LED may be mounted to a thin film with a conductive transparent coating comprising the electrical circuit which is then laminated. Alternately one or more wires may be embedded in the interlayer connecting the LED die. The transition to the exterior of the laminate is also typically made by means of a thin conductor/insulating layer connector.

Similar methods are used with the other types of components that may be needed.

For more complex circuits requiring multiple electrical connections, especially when spread over a large area, flexible printed circuits have been used.

Flexible printed circuits are printed circuit boards that can bend. A flexible printed circuit comprises a conductive layer such as copper, bonded to one or more insulating layers, typically a polyimide. The thickness of the conductive layer can range from 2 μm to over 200 um. The insulating layer thickness can vary from 10 μm to over 200 μm. A thin adhesive layer is used to bond the layers, although non-adhesive means are also used. The conductive layer is used to form the traces of the circuit. The conductive circuit itself is not typically printed but rather produced by a photo-lithographic etching process. The total thickness of the flexible circuit typically varies from 25 μm to about 1000 μm.

While flexible circuits are economical for multiple connections that are close to each other, they rapidly become impractical if the connections are too far apart. This is because of the manufacturing process used to fabricate them. When the connection points are far apart, standard practice has been to have multiple connectors with each located close to the connection point of the embedded circuit. This is undesirable as the wiring harness must be routed to more than one location.

Flexible circuits are made by laminating together rectangular sheets of thin flat insulating and conducting layers. If, as an example, we need to provide power to a component embedded within a laminate where the connection points run along opposite sides of the laminate, then the areas of the rectangles of raw material need to be large as the circuit must reach the opposite sides of the laminate, even though the final circuit may have an area that is a small fraction of the original surface area of the raw material. A large amount of expensive material is wasted. In addition, while flexible circuit manufacturing is a mature industry, most of the market for devices is requiring circuits that are much smaller than the typical automotive laminate making it difficult to find a fabricator having sufficient capability.

While the circuits are flexible, the general rule of thumb is that the minimum bend radius is equal to no less than ten times the circuit thickness. This rules out the possibility of folding the flexible circuit over onto itself inside of the laminate. While copper is ductile, it will undergo permanent plastic deformation if bent to too small of a radius. In addition, the folded circuit will have double the thickness in the folded area presenting lamination problems due to the increased thickness and abrupt rate of change in the thickness.

One work around used to reduce the quantity of material wasted is to manufacture the flexible circuit in segments. However, the segments then need to be joined together adding to the labor required and complexity. Another drawback to this approach is that the added thickness in the area where the segments overlap can present lamination problems.

A cost-effective flexible circuit would be highly advantageous for automotive laminates with complex electrical circuits.

### BRIEF SUMMARY OF THE DISCLOSURE

The present disclosure provides a solution for the above-mentioned issues by proposing a flexible electrical circuit configured to be embedded into a laminated glazing for a vehicle, comprising: at least one insulating layer; at least one conductive layer bonded to at least one insulating layer; and at least one folded area having a sharp fold in said flexible circuit wherein the flexible circuit is folded over onto itself forming a crease. The flexible electrical circuit has at least a portion configured to provide a folded area with a crease such as to obtain two segments on each side of the crease that change directions.

In another aspect of the invention, the present disclosure discloses a laminate comprising at least two glass layers, at least one interlayer, at least one electrical component embedded within the laminate, and a flexible circuit electrically connected to at least one electrical component wherein the flexible circuit has at least one sharp fold wherein the flexible circuit is folded over onto itself forming a crease.

Each glass layer has two major surfaces and an edge surface. The interlayer is positioned between the opposite major surfaces of the glass layers and serves to permanently bond the layers of the laminate to each other. At least one electrical component, which requires at least one electrical connection, is embedded within the laminate. The electrical device is electrically connected by means of a flexible circuit. The flexible circuit has at least one insulating layer and at least one conductive layer. The conductive layer is configured to form an electrical circuit. The flexible circuit is designed to have a thickness that is equal to or less than the maximum thickness that can be laminated. Optionally, a portion of at least one insulating layer may be removed such that when the flexible circuit is folded the total thickness in the folded area is reduced. Pressure and/or heat may optionally be used to further reduce the thickness of the sharp fold.

### ADVANTAGES

Less material wasted.
Lower cost.
Facilitates assembly of the laminate.
Enables complex circuitry.
Lower storage footprint.
Lower handling cost.

### BRIEF DESCRIPTION OF THE SEVERAL VIEWS OF THE DRAWINGS

FIG. 1A is a top view of the unfolded flexible circuit according to one embodiment of this disclosure with four conductive traces.

FIG. 1B is a side view of unfolded flexible circuit according to one embodiment of this disclosure with four conductive traces.

FIG. 2A is the cross-section AA of FIG. 1A.

FIG. 2B is the cross-section BB of FIG. 1B.

FIG. 3 is the isometric view of the unfolded flexible circuit according to one embodiment of this disclosure with four conductive traces.

FIG. 4 is the isometric view showing the flexible circuit according to one embodiment of this disclosure being folded to final shape in steps of 45, 90, 135 and 180 degrees.

FIG. 5 is the top view of the folded flexible circuit according to one embodiment of this disclosure.

FIG. 6 is the cross-section CC of FIG. 5.

FIG. 7 Is the Cross-section Dd of FIG. 5.

FIG. 8 is the side view of a PDLC sidelite window with the folded flexible circuit according to one embodiment of this disclosure.

FIG. 9 is an exploded isometric view of the unfolded flexible circuit of FIG. 15.

FIG. 10A is the top view of the flexible unfolded circuit of FIGS. 8 and 9.

FIG. 10B is the layer one and the adhesive layer one of the flexible circuit of FIG. 10A.

FIG. 10C shows the conductive traces of the flexible circuit of FIG. 10A.

FIG. 10D is the layer two and the adhesive layer two of the flexible circuit of FIG. 10A.

FIG. 11 is the top view of a PDLC panoramic laminated roof with fourteen PDLC segments utilizing the flexible circuit with two folds according to one embodiment of this disclosure.

FIG. 12 is the detail “A” of FIG. 11.

FIG. 13 is the detail “B” of FIG. 11.

FIG. 14 is the detail “C” of FIG. 11.

FIG. 15 is the detail “D” of FIG. 11.

FIG. 16 is the foldable flexible circuit according to one embodiment of this disclosure with separate external connector.

FIG. 17A is a large unmodified flexible circuit of the prior art.

FIG. 17B is the flexible circuit of FIG. 17A as modified by the disclosure to the unfolded form.

FIG. 17C is the large flexible circuit of FIG. 17B in the folded form with two sharp folds.

FIG. 18A is the flexible circuit of FIG. 17C further modified with additional sharp folds so as to reduce the block size.

FIG. 18B is the large flexible circuit of FIG. 18A in the folded form with four sharp folds.

FIG. 19A is the flexible circuit of FIG. 11 in the folded form.

FIG. 19B is the flexible circuit of FIG. 11 in the unfolded form.

FIG. 19C is the flexible circuit of 19B further modified with additional sharp folds so as to reduce the block size.

FIG. 20A is a flexible circuit having one of the insulating layers partially removed at the area of the sharp fold.

FIG. 20B is the cross-section EE of the flexible circuit of FIG. 20A.

### REFERENCE NUMERALS OF DRAWINGS

2 Glass
4 Bonding/Adhesive layer (plastic Interlayer)
6 Obscuration/Black Paint
20 Flexible circuit Adhesive 1
22 Flexible circuit Layer 1
24 External connector
26 Conductive trace
28 Crease line
30 Flexible circuit Adhesive 2
32 Flexible circuit Layer 2
34 Electrical connector 1
38 Flexible circuit 1
42 PDLC film
44 Electrical connector 2
48 Flexible circuit 2
50 PDLC layer 1
52 LASER ablation
52 PDLC Emulsion
60 PDLC layer 2
64 Beltline
66 Opening
68 Unfolded flexible circuit
70 Folded flexible circuit
101 Exterior side of glass layer 1 (201), number one surface.
102 Interior side of glass layer 1 (201), number two surface.
103 Exterior side of glass layer 2 (202), number three surface.
104 Interior side of glass layer 2 (202), number four surface.
201 Outer glass layer
202 Inner glass layer

### DETAILED DESCRIPTION OF THE DISCLOSURE

The present disclosure can be understood more readily by reference to the detailed descriptions, drawings, examples, and claims in this disclosure. However, it is to be understood that this disclosure is not limited to the specific compositions, articles, devices, and methods disclosed unless otherwise specified and as such can vary. It is also to be understood that the terminology used herein is for the purpose of describing aspects only and is not intended to be limiting.

Typical automotive laminated glazing cross-sections are comprised of two layers of glass 2, the exterior or outer glass layer 201, and interior or inner glass layer 202, that are permanently bonded together by a bonding layer 4 (interlayer). Each glass layer has two major surface and an edge. In a laminate, the glass surface that is on the exterior of the vehicle is referred to as surface one, 101, or the number one surface. The opposite face of the exterior glass layer 201 is surface two, 102, or the number two surface. The glass 2 surface that is on the interior of the vehicle is referred to as surface four, 104, or the number four surface. The opposite face of the interior layer of glass 202 is surface three, 103, or the number three surface. Surfaces two, 102, and three, 103, are bonded together by the bonding layer 4. An obscuration 6 may be also applied to the glass. Obscurations are commonly comprised of black enamel frit printed on either the number two, 102, or number four surface, 104, or on both. The laminate may have a coating on one or more of the surfaces. The laminate may also comprise a film laminated between at least two bonding layers 4.

The following terminology is used to describe the laminated glazing of the disclosure.

The term “glass” can be applied to many inorganic materials, including many that are not transparent. For this document we will only be referring to transparent glass. From a scientific standpoint, glass is defined as a state of matter comprising a non-crystalline amorphous solid that lacks the long-range ordered molecular structure of true solids. Glasses have the mechanical rigidity of crystals with the random structure of liquids.

Glass is formed by mixing various substances together and then heating to a temperature where they melt and fully dissolve in each other, forming a miscible homogeneous fluid.

The types of glass that may be used include but are not limited to the common soda-lime variety typical of automotive glazing as well as aluminosilicate, lithium aluminosilicate, borosilicate, glass ceramics, and the various other inorganic solid amorphous compositions which undergo a glass transition and are classified as glass included those that are not transparent. The glass layers may be comprised of heat absorbing glass compositions as well as infrared reflecting and other types of coatings.

Laminates, in general, are articles comprised of multiple layers of thin, relative to their length and width, material, with each thin layer having two oppositely disposed major surfaces, typically of uniform thickness, which are permanently bonded to one and other across at least one major surface of each layer. The layers of a laminate may alternately be described as sheets or plies. In addition, the glass layers of a glazing may be referred to as panes.

Laminated safety glass is made by bonding two layers of annealed glass together using a polymer bonding layer comprised of a thin sheet of transparent thermoplastic (interlayer).

Safety glass is glass that conforms to all applicable industry and government regulatory safety requirements for the application.

Annealed glass is glass that has been slowly cooled from the bending temperature down through the glass transition range. This process relieves any stress left in the glass from the bending process. Annealed glass breaks into large shards with sharp edges. When laminated safety glass breaks, the shards of broken glass are held together, much like the pieces of a jigsaw puzzle, by the polymer layer helping to maintain the structural integrity of the glass. A vehicle with a broken windshield can still be operated. The polymer layer also helps to prevent penetration by objects striking the laminate from the exterior and in the event of a crash occupant retention is improved.

All windshields are required by law to be annealed, laminated, safety glass.

While laminated glass is only required for the windshield, it is being used in other positions increasingly.

The polymer bonding layer (interlayer) component has the primary function of bonding the major faces of adjacent layers to each other. The bonding interlayer may be a solid layer or a liquid that is subsequently cured and transformed into a solid. The material selected is typically a clear solid thermoplastic polymer. While there are numerous transparent plastics, few have the required level of adhesion to glass and can survive the extremes of temperature and UV exposure for the life of the vehicle.

For automotive use, the preferred bonding layer (interlayer) is polyvinyl butyral (PVB). In addition to being the most economical, PVB has excellent adhesion to glass and is optically clear once laminated. Automotive PVB is a highly engineered and optimized material.

Unless otherwise noted drawings are not to scale.

While the focus of the embodiments and discussion is on laminated roofs and sidelite windows, it can be appreciated that the disclosure is not limited to roofs and sidelites. The disclosure may be implemented in any of the other glazing positions of the vehicle. In addition, the disclosure may be practiced with any type of glazing and is not limited to automotive. Likewise, the folded flexible circuit is not limited to VLT films and may be used to connect any electrical circuit or component embedded within the glazing. In addition, for the sake of clarity fold angles of only 90 degrees are shown. It can be appreciated that this is not a limitation and that any fold angle can be used.

Flexible circuits are manufactured by means of a lamination process. In the first step of the process, at least one insulating layer is first laminated to at least one conductive layer. A polyimide layer is usually used as the insulating layer due to its durability and temperature resistance. The conductive layer is typically a thin copper sheet. An adhesive layer may be used. Insulating layers are available that can be directly laminated to the conductive layer without an adhesive. Next, the conductive layer is coated with a photo-resist. The photo-resist is exposed by projecting the image of the circuit to be formed onto the photo-resist. The areas that are not exposed and cured by the exposure are then washed off. The exposed conductive layer is then removed leaving behind the circuit traces. A second insulating layer may then be laminated to the conductive layer. Each insulating layer may be cut to remove area of insulation exposing the conductive layer. Several flexible circuits may be nested in a single larger rectangle during manufacture.

The smallest rectangle in which the unfolded flexible circuit can fit is called the block size. We here define the length of the block to be the greater of the two lengths of the sides of the rectangle. The width is the lesser of the two dimensions. If the block is a square, then the length is equal to the width.

The flexible electrical circuit of the disclosure has at least a portion configured to provide a folded area with a crease such as to obtain two segments on each side of the crease that change directions. The crease is a sharp fold made onto the flexible circuit wherein the flexible circuit folds over itself. Optionally, a pre-bending step may be carried out onto the folding area prior to folding such as to create a crease line prior to folding. To decrease thickness in the folding area, at least one of the insulating layers is at least partially removed in the folding area. To provide mechanical resistance to the folding area during folding, the at least one insulating layer is partially following the crease line in such a way that on one side of the crease line the at least one insulating layer is present and on the other side of the crease line the at least one insulating layer is partially removed.

The main advantage of the flexible electrical circuit of the disclosure is that it can be manufactured in a small block size compared to the electrical circuit of the prior art. The folded areas make it possible to reduce the size of the block size such as to allow saving many and material resources.

Additional layers may be added by repeating these steps. A flexible circuit may have multiple layers the same as a conventional rigid printed circuit. After all of the layers have been laminated, additional steps such as the drilling of holes and the application of a protective coating over traces may be done.

The thickness of the insulating layers, adhesive layer, and conductive layer will vary with the application. Likewise conductive trace width and spacing will also vary with the application.

Flexible circuit manufacturing is a mature industry with thousands of suppliers worldwide. Most suppliers, however, service the electronics market where the typical circuit is not as large as the typical glazing. Fortunately, flexible circuits are nested, and the equipment used to manufacture the circuits can process sheets that are fairly large. However, there are limits.

Most suppliers would not have the capability to produce a flexible circuit large enough to span a large panoramic roof.

The method of manufacture herein described is commonly used to fabricate flexible circuits. However, a method may be used that deviates from that described and as such this method is not to be considered as a limitation. Other methods may be used.

Looking at the panoramic roof of FIG. 11, we can see that the block size and the correspondingly sized raw insulating and conducting layer flat sheets required would be quite large. The roof measures around 1,600 mm by 900 mm. There are very few flexible circuit fabricators who would be able to manufacture a circuit this large. Each insulating layer and the conductive layer would need to be around 1,500 mm by 800 mm. The flexible circuit is 60 mm wide along the left side of the roof and 18 mm wide along the other two sides. Thus, around 90% of the material would be wasted if such a flexible circuit would be manufactured using conventional methods described in the current state-of-the-art.

As stated, the rule of thumb for the flexible circuit bend radius is that the minimum bend radius of a flexible circuit is ten times its thickness. The other limit is the one third guideline for the thickness of laminated objects with respect to the total thickness of the interlayers. With two 0.76 mm layers of PVB, giving the laminate a total interlayer thickness of 1.52 mm, the flexible circuit thickness must be no more than around 0.5 mm. Even at 0.5 mm there could be lamination issues due to the abrupt change in thickness at the edges of the flexible connectors, so even thinner is better.

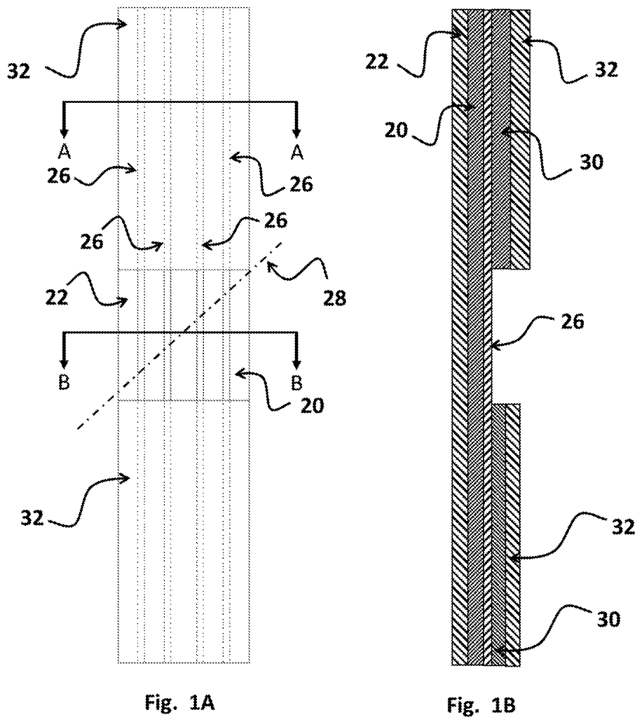

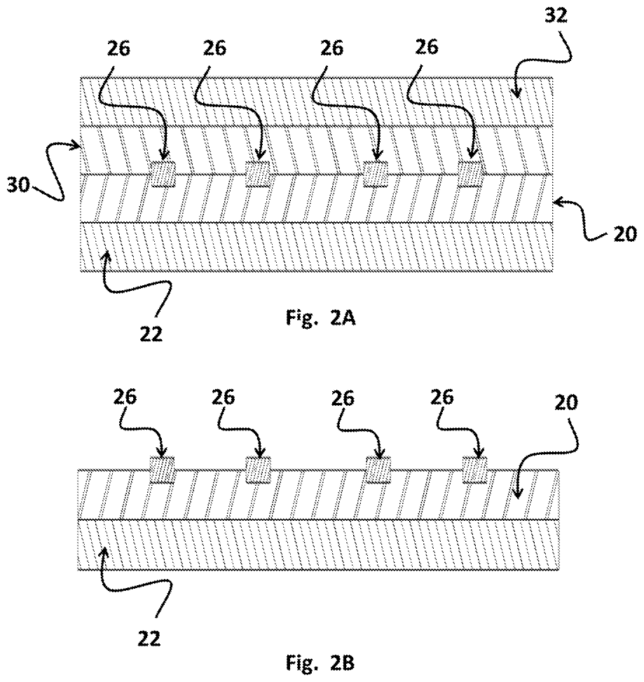

FIGS. 1A and 1B show the top view and side view of an example of the flexible circuit of the disclosure. FIGS. 2A and 2B show cross sectional views AA and BB of the flexible circuit of FIGS. 1A and 1B. Section AA shows the portion of the flexible circuit that has two insulating layers. Section BB shows the portion where there is just one insulating layer. The flat flexible circuit with no folds is what we shall designate as the unfolded flexible circuit.

The flexible circuit illustrated in these figures has two insulating layers 22 and 32 with a thickness of 50 μm, two adhesive layers 20 and 30 with a thickness also of 50 μm and four conductive traces 26, made of copper with a thickness of 70 μm for a total thickness of 270 μm. Therefore, we should not be able to fold the circuit to a bend radius of less than 2.7 mm (which is ten times the total thickness of the flexible circuit).

Surprisingly, it has been discovered that the flexible circuit can be sharply folded over onto itself leaving a crease with a radius that is approximately the same or less than the thickness of the flexible circuit. This sharp fold can only be made once. The conductors 26 will undergo plastic deformation along the crease line 28 (shown in FIGS. 1A, 2 and 3) and cannot be unfolded without a high probability of breakage. However, the flexible circuit only needs to be sharply folded once during or prior to the assembly of the laminate.

If we were to sharply fold the flexible circuit of this example over onto itself such that the fold is essentially flat with respect to the length of the flexible circuit, the thickness would be doubled to 540 μm in the folded area which could present lamination problems due to the total thickness as well as the abrupt change in thickness.

Even if the thickness in the folded area is less than a third of the total interlayer thickness, thinner is always going to be less prone to problems. When comparing the thickness of the flexible circuit in the folded area to the thickness in the unfolded area immediately adjacent to the folded area, it is desirable to have the thickness of the flexible circuit in the folded area to be less than or equal to double the thickness of the flexible circuit in the unfolded area, preferably less than one and one half the total and more preferably less than or equal to the total thickness of the unfolded area.

There are a number of methods that can be used to facilitate lamination and eliminate or minimize the folded circuit thickness and associated problems.

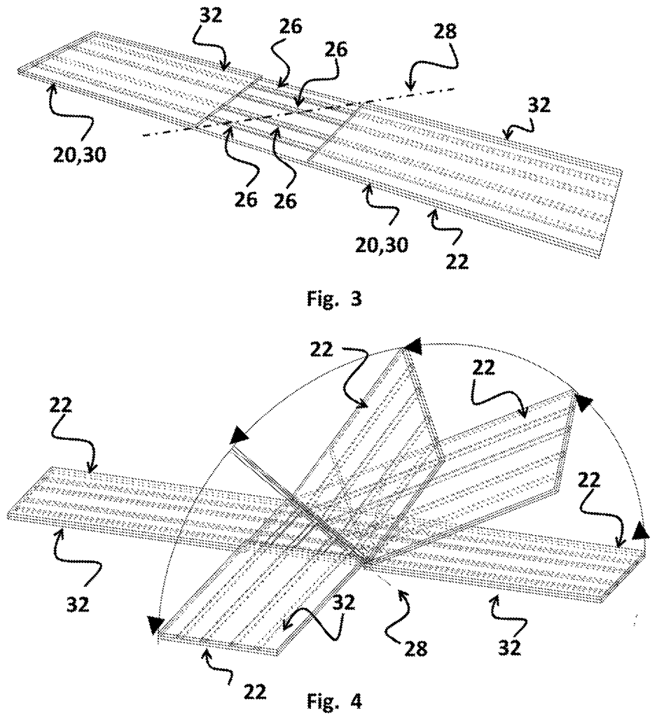

In the first method, to avoid the increase in thickness, insulating layer two 32 may be removed in the area where the circuit will be folded over as illustrated in FIG. 3. In FIGS. 3 and 4 the crease about which the flexible circuit is folded is shown. A portion of the insulating layer two 32 is removed leaving only the insulating layer one 22 and the conductive traces 26 exposed. The crease line 28 (folding line) runs diagonally through the rectangle created by the insulating material removed. The fold is done such that the copper traces 26 are on the outside of the fold as shown in FIG. 2B. As the glass 2 and interlayer 4 of the laminate are excellent electrical insulators and the exposed conductive layers of the flexible circuit (conductive traces 26) are embedded within the laminate, there is no risk of an electrical short. In fact, the second layer of insulating layer is primarily used to improve durability and handling. The insulating properties are only needed when the flexible circuit exits the laminate.

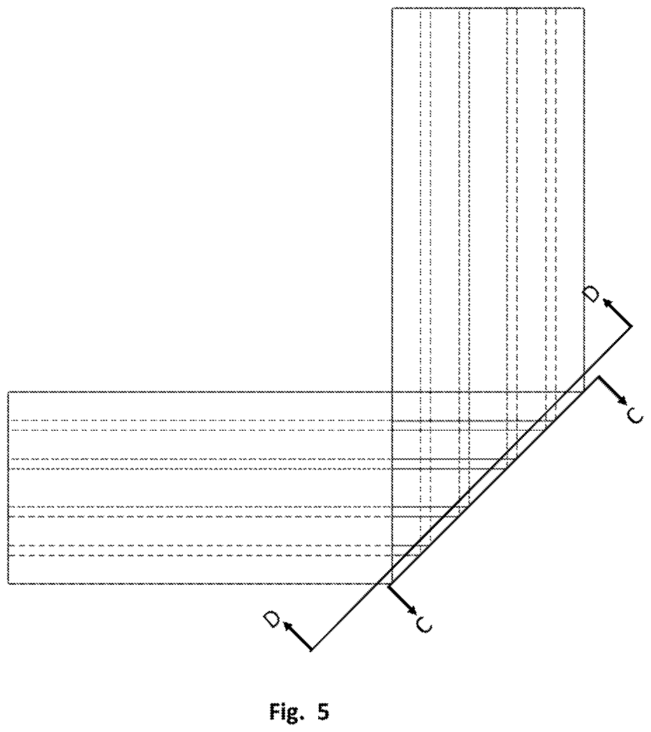

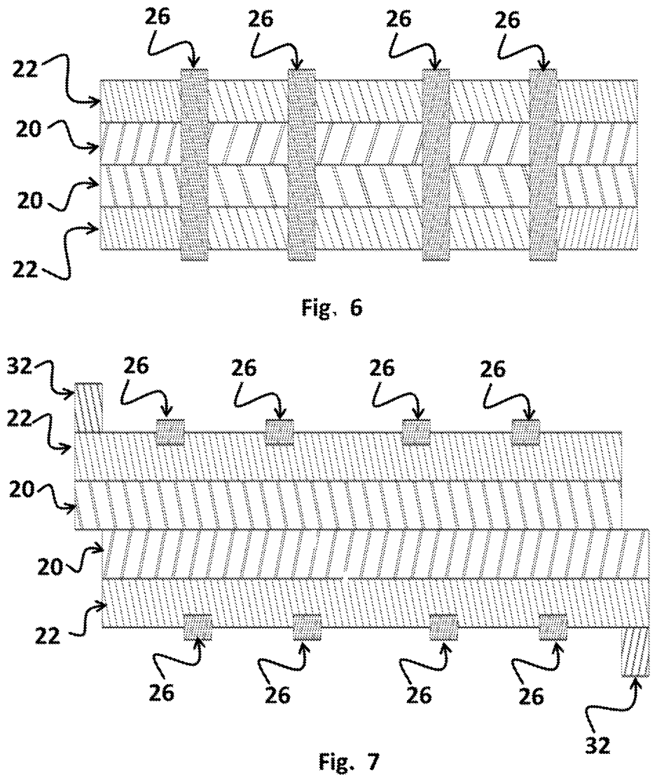

This method is shown in FIG. 4 where the unfolded circuit from FIGS. 1 and 3 is folded in 45-degree steps along the crease line 28 to the final folded shape as shown in FIG. 5. Cross sections CC and DD are shown in FIGS. 6 and 7. Section DD, FIG. 7, is cut 3 mm inboard from the crease line. Section CC, FIG. 6, is cut right at the very edge of the crease. In section CC we can see that the insulating layer 20 is folded over onto itself as the conductive traces 26 wrap around the other surface of the crease line.

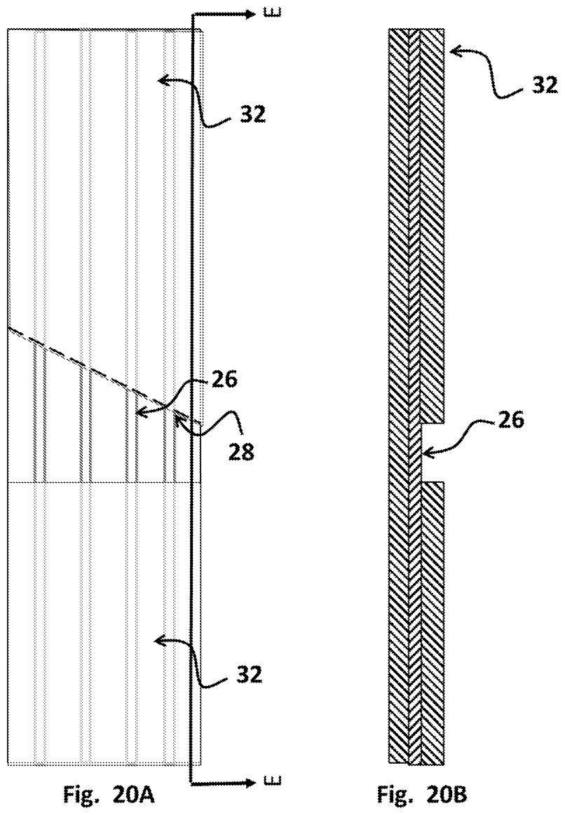

Advantageously, a pre-bending step can be performed such as to form a crease line onto the region where the flexible circuit should be folded onto itself prior to folding. While the pre-bending step may be beneficial to improve the quality of the sharp fold, it may also damage the flexible circuit because of lack of insulation layer on the crease line. Therefore, in one advantageous aspect of the invention the insulating layer should be partially removed from the folding area in such a way that the insulating layer follows the crease line on one side of the crease and is partially removed on the other side of the crease. This is illustrated in FIG. 20A. The cross-section EE is shown in FIG. 20B. The cross-section EE is oversimplified by just showing one conductive layer 26 and two insulating layers 22 and 32, however any additional layers may also be present, such as adhesive layers (20, 30), protective layers among others, without departing from the spirit of the invention.

We note that the drawings are not to scale and that some features are exaggerated for illustrative purposes. While the conductive traces are shown embedded between two uniform layers of adhesive, in practice, the traces would likely be wider with less space between, and the adhesive would be more likely to flow between the conductive traces than for the traces to become embedded within the adhesive. This is important as the conductive traces do contribute to the total thickness of the flexible circuit. The actual thickness may vary across the width of the circuit due to the presence or absence of conductive traces.

The thickness of the layers may be selected such that the total thickness in the folded area with a portion of one or both of the insulating layers removed is substantially the same as in the unfolded area.

We note that while the conductive layer thickness will double where it overlaps, under pressure the high points will tend to be pressed into the softer adhesive and insulating layers.

The same principle may be applied to a flexible circuit when a portion of the insulating layer is not removed. The sharp fold will double the thickness of the flexible circuit. If the thickness causes a lamination problem, pressure and/or heat if needed may be applied to the fold so as to flatten it out, compressing the insulating and adhesive layers.

Another method is to simply make the flexible circuit thinner so that when sharply folded the total thickness does not cause a problem. This is often not as difficult to accomplish as it may as first appear to be.

The thickness of the layers is often decided more by factors other than the current carrying capability and insulating properties of the material. Thinner materials can sometimes be more expensive due to difficulty in controlling thickness to within a narrow specification, greater difficulty in handling, a higher probability of breakage and other factors. There are also a small number of thicknesses that the industry has standardized upon. Using a non-standard thickness will increase the cost of the raw materials. In addition, in conventional electrical devices, the thickness of the flexible circuit is not typically a high concern. Often the thickness of the insulating and conducting layers is much greater than needed for the electrical function but is rather dictated by consideration of the cost, handling, and durability of the flexible circuit. VLT films, SPD, PDLC and LC have a very high DC resistance. While the voltage may be relatively high (50-100 VAC), the current is very low. The conductive traces are size not on current carrying capacity. Flexible circuits for VLT films are typically made with standard thickness insulating, adhesive and conducting layers and selected more for their durability. We can easily reduce the thickness while maintaining the electrical functionality of the circuit. Care must be taken during handling but the increase in the probability of breakage is not that great with the slight reduction in thickness needed in this example.

The flexible circuit show in FIG. 2A, was described as comprising two insulating layers 22 and 32 and two adhesive layers 20 and 30 with a thickness of 50 μm and copper traces 26 with a thickness of 70 μm for a total thickness of 270 μm. If we were to sharply fold the circuit over such that the fold is essentially flat, the thickness would be doubled to 540 μm. At this thickness, the folded area thickness is right at the limits.

However, we can easily reduce the thickness of all three of the layers. By using 25 μm thick insulating and adhesive layers with a 35 μm copper layer, the total thickness is reduced to 135 um and 270 μm in the sharply folded area. Further, while handling is slightly compromised the materials used are standard thicknesses and readily available.

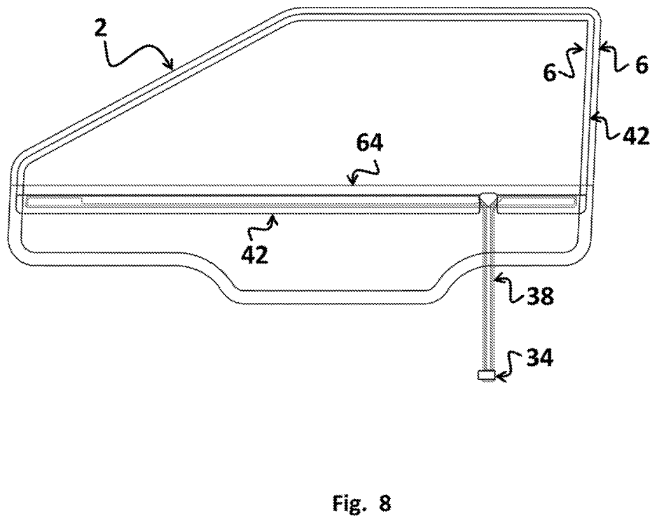

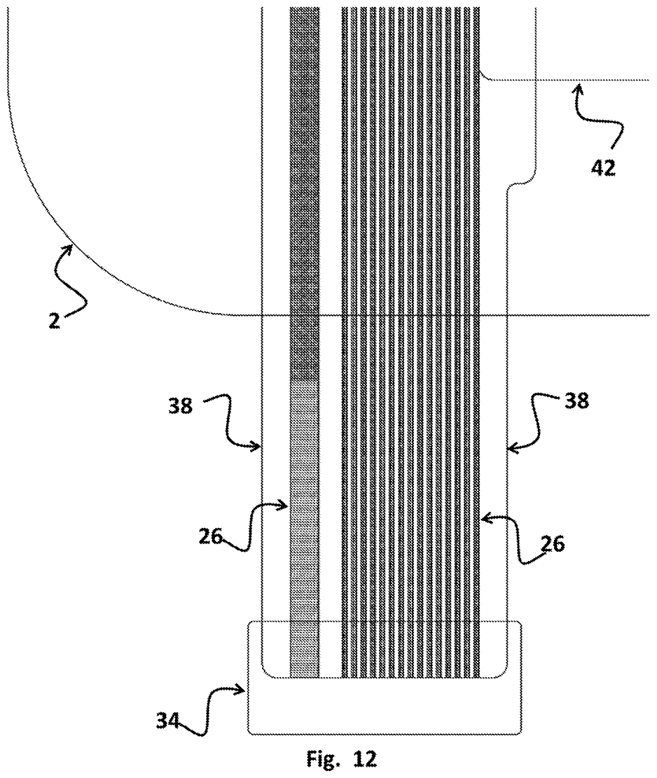

The flexible circuit may exit the laminate as shown in FIGS. 8 and 12. However, the flexible circuit may not have sufficient strength in the area where the flexible circuit extends outboard from the edge of glass. In this case we can add reinforcement layers to at least a portion of the flexible circuit in this area.

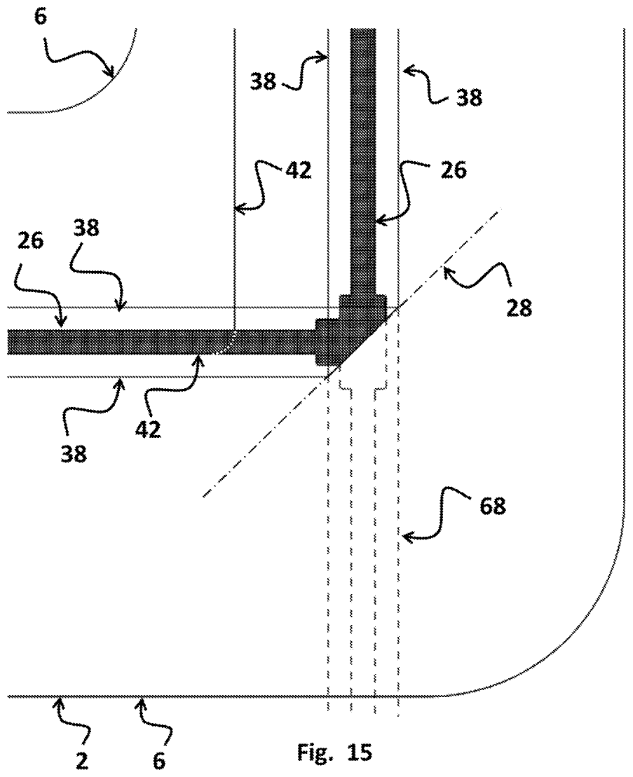

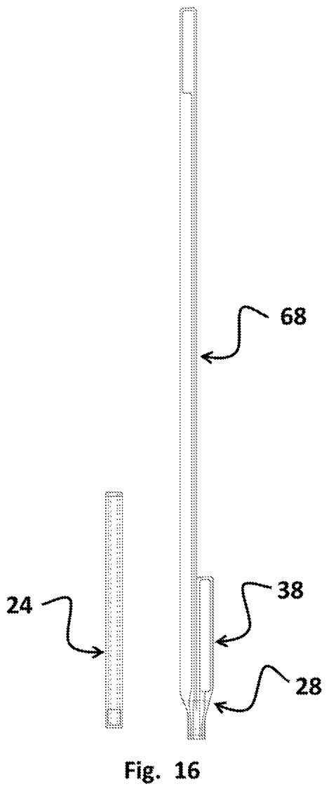

Alternately, we can use the folded flexible circuit just to make the internal electrical connections and then use a separate flexible circuit or connector, soldered to the folded flexible circuit, to exit the laminate. An example of this method is shown in FIG. 16. In FIG. 16, the flexible circuit illustrated in FIGS. 8, 9, 10A, 10B, 10C and 10D, which exits the bottom edge of glass, is modified. The length of the flexible circuit 38 is shortened, ending just below the two sharp fold creases 28. The flexible circuit will now be entirely enclosed within the laminate. In order to make contact with the wiring hardness, a second flexible circuit 24 of FIG. 16, is fabricated using thicker layers so as to reinforce the portion extending outboard of the edge of glass. As this second flexible circuit is not folded, the layers can be thicker. During assembly of the laminate, the two flexible circuits are electrically bonded together.

Some components do not require a solid conductor to make an electrical connection. Externally mounted cellular antennas typically made use of capacitive coupling through the glass as did a number of AM/FM embedded conductive coating antennas. Power can be transferred to an embedded component inductively as is commonly done with cell phones and various small appliances.

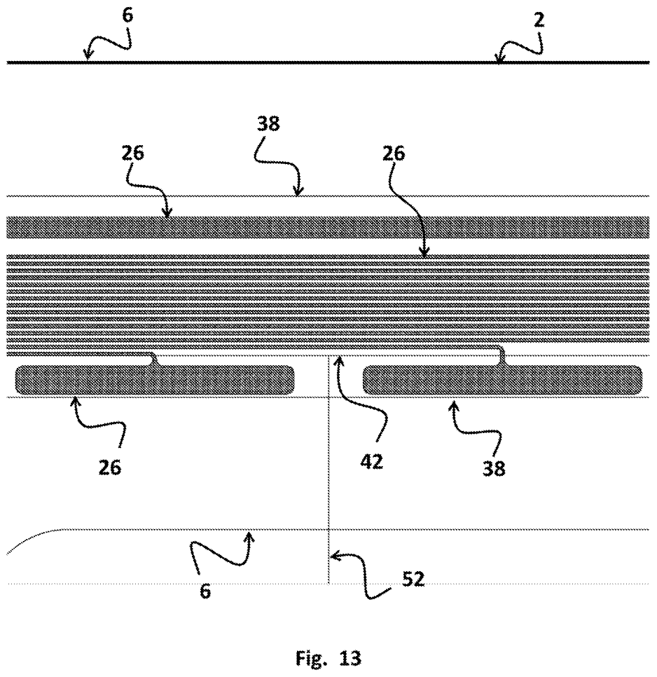

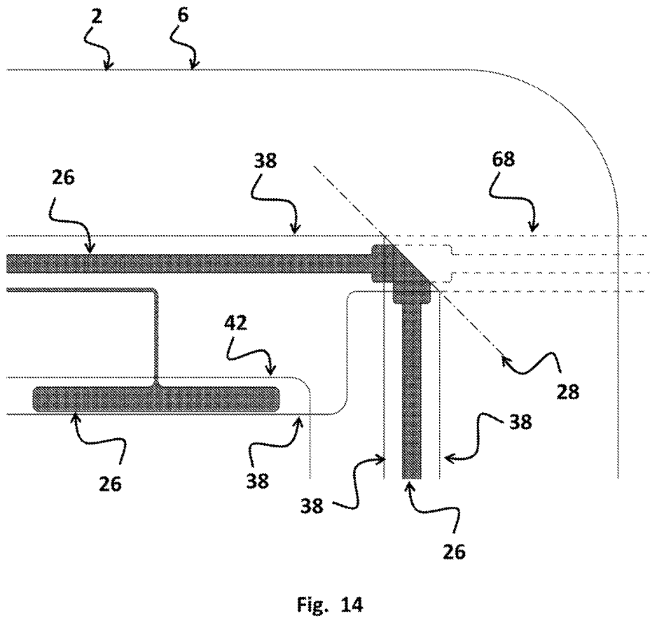

In the sharply folded area where the conductive layer bends, plastic deformation of the metal conductive layer occurs and the thickness of the conductor decreases. Optionally, we can compensate by increasing the width and cross-sectional area of the conductive layer. FIG. 11 shows an example of a panoramic roof having a flexible circuit. The details B and C illustrated in FIGS. 13 and 14 show a flexible circuit where the width of the conductive trace 26 is doubled in the area where the circuit is folded.

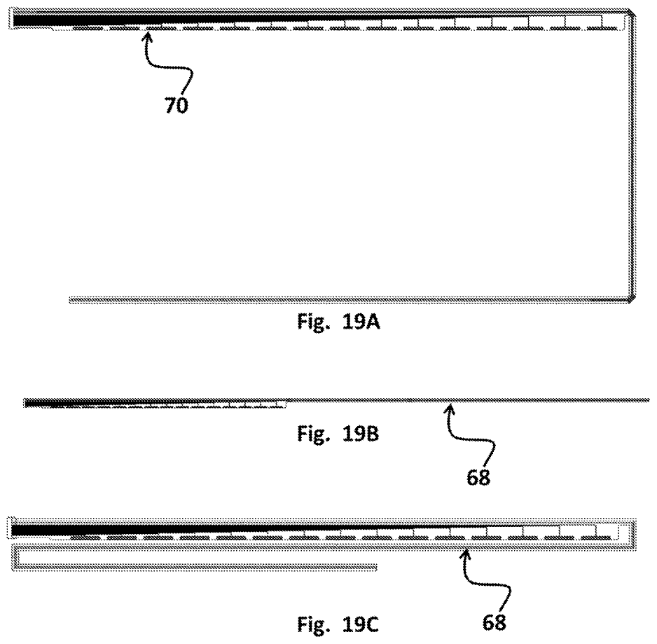

As mentioned, there is a limit as to the block size that can be processed when manufacturing flexible circuits. While it is possible to produce extremely long flexible circuits from roll stock, it is not common at least for the more complex circuits needed in some of the embodiments described. Looking at FIG. 19B, we see the unfolded version of the flexible circuit of the panoramic roof of FIG. 11. The length is close to 4 meters and far exceeds the capability of most flexible circuit manufacturers. This would also present storage and handling issues. However, it is possible to use the same method of sharp folds to further reduce the block size of the unfolded circuit. This optimized unfolded circuit is shown in FIG. 19C.

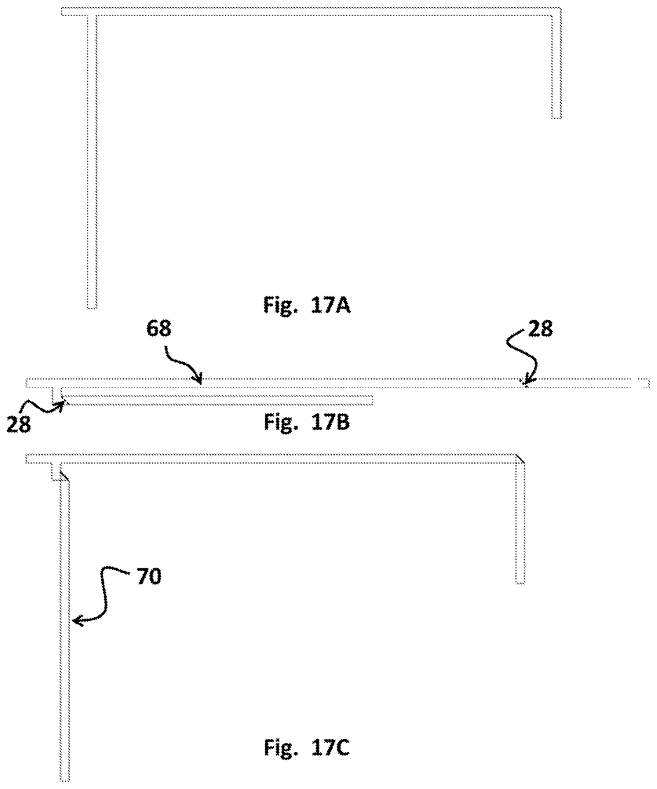

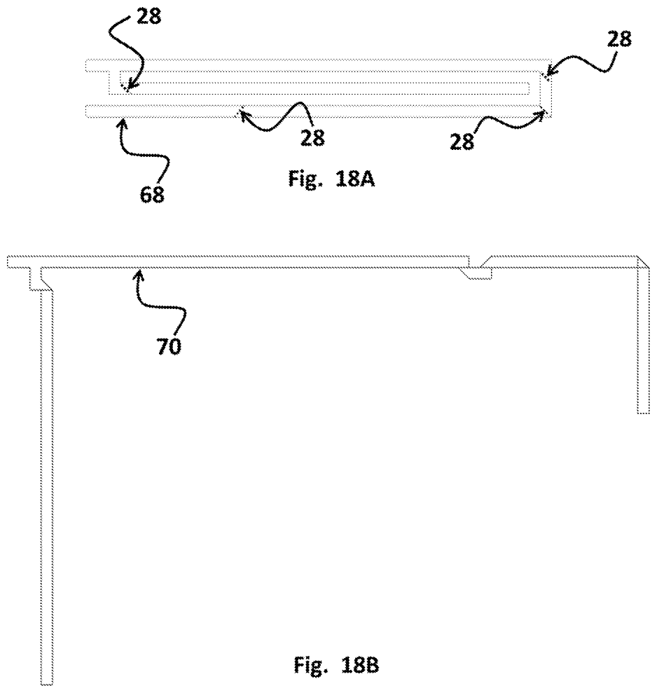

This method is further illustrated in FIGS. 17A, 17B, 17C, 18A and 18B. FIG. 17A shows how the circuit of the prior art would look without the use of the sharp folds of the disclosure. It is obvious that there would be a large quantity of wasted material. The only practical way to produce the circuit is to produce it in segments that are soldered together. Another method, common in the prior art is to make two separate circuits with two separate connectors.

The unfolded flexible circuit of the disclosure is shown in Figure. The unfolded circuit of FIG. 17B is shown in the folded form in FIG. 17C. Two sharp folds, 28 are used to reduce the block size of the unfolded circuit to a fraction of the original. Each of the two sharp folds create segments that change directions in relation one to one and another. The segment of the circuit that is on one side of the sharp fold (crease) follows in one direction whereas the segment on the other side of the crease goes to another direction.

However, even this version may have too great of a length. The initial two sharp folds shown in FIG. 17B substantially reduce the block width but increase the block length. In FIG. 18A the circuit of FIG. 17B is modified with the addition of two additional sharp folds allowing the length of the block to be substantially reduced. The unfolded flexible circuit of FIG. 18A is shown in the folded form in FIG. 18B. Comparing FIG. 18B and FIG. 17C, the two folded flexible circuits are electrically equivalent and accomplish the same component connections. The difference is that the flexible circuit of FIG. 18B consumed less resources to be manufactured and consequently could be made cheaper than the flexible circuit from FIG. 17C. For sake of comparison the flexible circuit of the prior-art shown in FIG. 17A is probably the most expensive one. The unfolded 68 circuit is shown in FIG. 17B and the folded in 17C. In this case one may conclude that the number of sharp folds is inversely proportional to the circuit block size. The larger is the number of sharp folds, the smaller is the area of the block size. As second example of this block length reduction method is shown in FIG. 19C where the block length of the circuit of FIG. 19B is reduced by adding two sharp folds and four 90-degree angles to the unfolded pattern. This method can be used to reduce the original block length and/or the original block width.

### DESCRIPTION OF EMBODIMENTS

1. Example one is a laminated front door sidelite window with a PDLC film embedded within the laminate. The outer glass layer 201 is a 2.6 mm thick, ultra-clear, soda-lime glass with a solar coating applied to surface two, 102. The inner glass layer 202 is 2.1 mm thick, solar green, soda-lime glass. A black frit obscuration 6 is screen printed onto surface two of the outer glass 201 and surface four, 104 of the inner glass layer prior to bending. After bending the two glass layers are assembled with the PDLC film and flexible circuit of FIG. 8 sandwiched between two layers of PVB interlayer 4. The PVB layer 4 which is in contact with surface two, 102, is of an extended UV block formulation.

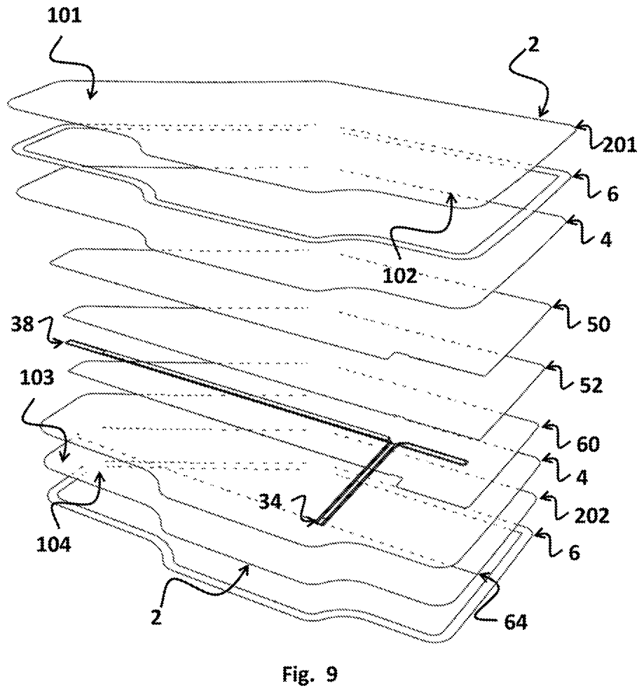

An exploded view of the sidelite window is shown in FIG. 9. The PDLC is comprised of two transparent conductive coated plastic layers 50 and 60 sandwiching a PDLC emulsion layer 52. The folded flexible circuit 38 is comprised of two 25 μm thick polyimide layers, 22 and 32, two 25 μm adhesive layers 20 and 30 and a 35 μm copper traces 26. There are two separate conductive traces 26. The circuit has two 90-degree folds forming a T shape. Each of the conductive traces 26 contacts each of the two opposite conductive coated layers of the PDLC film.

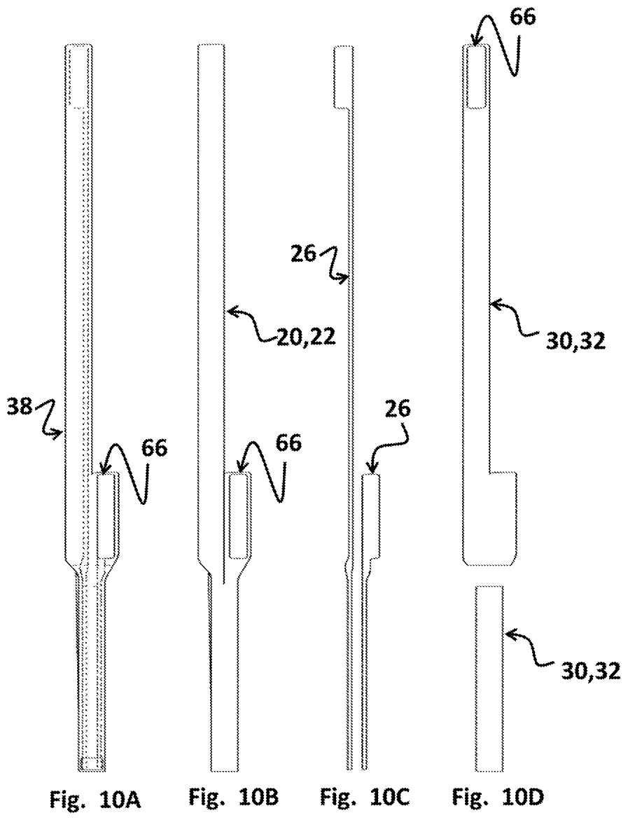

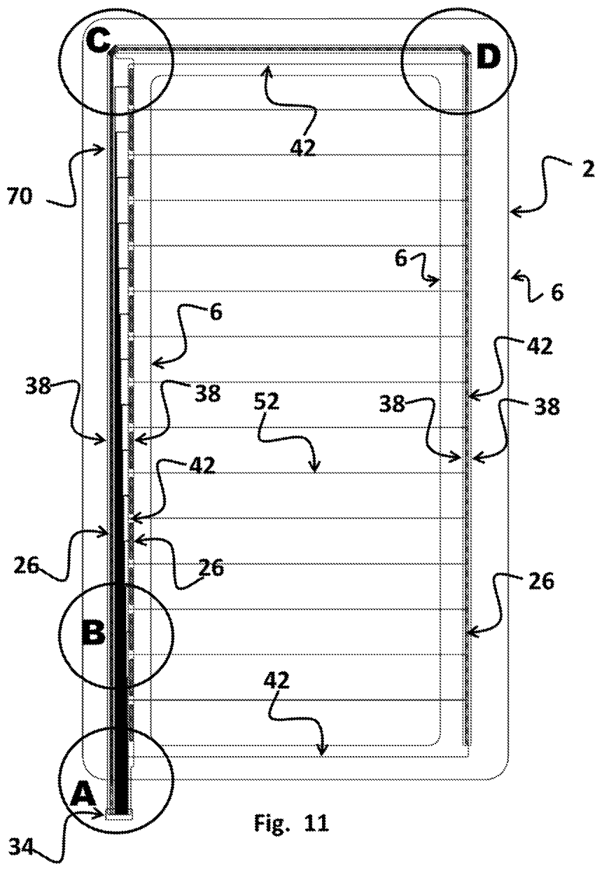

FIG. 10A shows a top view of the unfolded circuit as manufactured and supplied. FIG. 10B shows the insulating layer one, 22 and adhesive layer one, 20. FIG. 10C shows the copper traces 26, and FIG. 10D shows the insulating layer two, 32 and adhesive layer two, 30.
2. Example two is a large panoramic roof measuring around 1,600 mm by 900 mm, with a PDLC film embedded within the laminate. The outer glass layer 201 is a 2.8 mm thick, ultra-clear, soda-lime glass with a solar coating applied to surface two, 102. The inner glass layer 202 is 2.6 mm thick, dark solar green, soda-lime glass. A wide black frit obscuration 6 is screen printed onto surface two of the outer glass 201 and surface four, 104 of the inner glass layer prior to bending. After bending the two glass layers are assembled with the PDLC film and flexible circuit of FIG. 8 sandwiched between two layers of PVB interlayer 4. The PVB interlayer 4 in contact with surface two, 102 is of an extended UV block formulation. The second PVB interlayer 4 in contact with surface three, 103 has a dark grey tint with 20 % visible light transmission.

The PDLC film, prior to assembly, is processed by means of LASER ablation to divide the conductive coated area of the PDLC layer into fourteen separate electrically switchable portions emulating the slats of a conventional blind. LASER ablation is used to form the 14 separate are by electrically isolating the conductive coating on one of the transparent coated substrates. As a common neutral is used, no ablation is needed on the opposite second transparent conductive coated substrate. The two transparent conductive coated substrates have their coated sides opposite and facing each other with the liquid crystal emulsion sandwiched in between the two. The folded flexible circuit, shown in FIGS. 11, 12, 13, 14 and 15, has fourteen 1 mm wide copper traces separate by 1 mm each for the hot side of the circuit. Due to the very low current, this is more than adequate. The traces need not be 1 mm wide buy are made 1 mm wide just to facilitate and prevent damage during handling. The common is 6 mm wide.

The circuit has two 90-degree folds as shown in FIGS. 14 and 15. If we have openings on just one side, the first fold places them on opposite sides. The second fold places them back on the same side. Therefore, we must have openings in both of the insulating substrates so as to allow the copper to make contact with both of the transparent conductive coated layers.

The circuit extends for 100 mm beyond the edge of glass shown in FIG. 12. After final inspection, the connector 34 is crimped in place.

Embodiment one is similar to example one with the exception of the PDLC film. The PDLC film is replaced by an SPD film.

Embodiment two is similar to example one with the exception of the PDLC film. The PDLC film is replaced by an LC film.

Embodiment three is similar to example one with the exception of the PDLC film. The PDLC film is replaced by a transparent conductive coated sheet of 100 μm thick PET with fourteen groups of six LEDs in each group.

Embodiment four is similar to example two with the exception of the PDLC film. The PDLC film is red by an SPD film.

Embodiment five is similar to example two with the exception of the PDLC film. The PDLC film is red by an LC film.

Embodiment six is similar to example two with the exception of the flexible circuit cross section in the sharp fold areas. Portions of the insulating layers are not removed.

Embodiment seven is similar to example two with the exception of the flexible circuit cross section in the sharp fold areas. Portions of the insulating layers are not removed, and the sharp fold areas are subject to heat and pressure so as to reduce their thickness.

Embodiment eight is similar to example two with the exception of the portion of the flexible circuit that exits the edge of glass. The flexible circuit terminates inboard of the edge of glass. A second separate thicker reinforced flexible circuit which extends outboard of the edge of glass is electrically bonded to the first flexible circuit.

Embodiment nine is similar to example two with the exception of the unfolded shape of the flexible circuit. The flexible circuit illustrated in FIG. 19C is used.

Embodiment ten is similar to any one of the previous embodiments, except for one of the insulating layers. A portion of one of the insulating layers is cut such as to be removed in the folded area by following the crease line. On one side of the crease the insulating layer is present flush within the crease, whereas on the other side of the crease the insulating layer is partially removed.

1. A flexible electrical circuit configured to be embedded into a laminated glazing for a vehicle, comprising:
at least one insulating layer;
at least one conductive layer bonded to at least one insulating layer; and
at least one folded area having a sharp fold in said flexible circuit wherein the flexible circuit is folded over onto itself forming a crease.

2. The flexible electrical circuit of the preceding claim, having at least a portion configured to provide a folded area with a crease such as to obtain two segments on each side of the crease that change directions.

3. The flexible electrical circuit of any of the preceding claims, wherein the total thickness of the flexible electrical circuit comprising all of the at least one insulating and the at least one conductive layers is equal to or above 25 μm and equal to or less than 1000 μm.

4. The flexible electrical circuit of any of the preceding claims, wherein the thickness of the at least one sharp fold crease is reduced when compared to the total thickness of the portion immediately adjacent which comprises all of the at least one insulating and at least one conductive layers.

5. The flexible electrical circuit of any of the preceding claims, wherein the radius of the at least one sharp fold is less than or equal to the thickness of the flexible circuit.

6. The flexible electrical circuit of any of the preceding claims, wherein the total thickness in the folded area is less than double the total thickness of the portion immediately adjacent which comprises all of the of the at least one insulating and at least one conductive layers.

7. The flexible electrical circuit of any of the preceding claims, wherein a portion of at least one insulating layer is removed in the folded area.

8. The flexible electrical circuit of any of the preceding claims, wherein a portion of at least one of the at least one insulating layer is removed following the crease line in such a way that on one side of the crease the insulating layer is present and on the other side of the crease the insulating layer is partially removed.

9. The flexible electrical circuit of any of the preceding claims, wherein the total thickness in the folded area is less than one and one half the total thickness of the portion immediately adjacent that comprises all of the of the at least one insulating and at least one conductive layer.

10. The flexible electrical circuit of any of the preceding claims, wherein the total thickness in the folded area is substantially the same or less than that of the total thickness of the portion immediately adjacent that comprises all of the of the at least one insulating and at least one conductive layer.

11. The flexible electrical circuit of any of the preceding claims, wherein the width of the at least one conductive layer is increased in the folded area.

12. The flexible electrical circuit of any of the preceding claims, wherein the at least one conductive layer is comprised of copper.

13. A laminated glazing, comprising:
at least two glass layers with each comprising two oppositely disposed major surfaces and an edge surface;
at least one bonding interlayer wherein said interlayer is positioned between major surfaces of the at least two glass layers;
at least one electrical component embedded within said laminated glazing; and
a flexible electrical circuit of any of the preceding claims which is connected to said at least one electrical component, and is at least partially embedded to said laminated glazing.

14. The laminated glazing of claim 13, wherein the thickness of the at least one sharp fold of the flexible circuit is less than or equal to one third of the total thickness of all of the at least one bonding interlayer.

15. The laminated glazing of any of claims 13 and 14, wherein the at least one electrical component is selected from the following list: an SPD film, an LC film, a PDLD film, an LED, a touch sensor, a distance sensor, an antenna, a temperature sensor, a display, an RFID, a sound transducer, a heated circuit.

16. The laminated glazing of any of claims 13 to 15, wherein at least one portion of the flexible circuit exits the edge of the at least two glass layers by extending outboard them.

17. The laminated glazing of claim 16, wherein the at least one portion of the flexible circuit that extends outboard of the edge of the at least two glass is reinforced.

18. The laminated glazing of any of claims 13 to 15, wherein the flexible circuit is electrically connected to a second flexible circuit or connector which exits the edge of the at least two glass layers.

19. The laminated glazing of any of claims 13 to 18, wherein the glazing is a sidelite window, roof, windshield or backlite.

20. A vehicle comprising the glazing of any of claims 13 to 19.
